(19) United States
(12) Patent Application Publication
(10) Pub. No.: US 2023/0307532 A1
(43) Pub. Date: Sep. 28, 2023

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Noriaki YAO, Matsumoto-city (JP); Yoshihisa SUZUKI, Matsumoto-city (JP); Hiroshi TAKISHITA, Matsumoto-city (JP)

(21) Appl. No.: 18/320,995

(22) Filed: May 21, 2023

Related U.S. Application Data
(63) Continuation of application No. PCT/JP2022/024088, filed on Jun. 16, 2022.

(30) Foreign Application Priority Data
Jun. 17, 2021 (JP) 2021-100678

(51) Int. Cl. H01L 29/739; H01L 29/66; H01L 21/265

(52) U.S. Cl. CPC H01L 29/7397; H01L 29/66348; H01L 21/26513

(57) ABSTRACT

Provided is a semiconductor device including a drift region of a first conductivity type which is provided in a semiconductor substrate, a buffer region of the first conductivity type which is provided in a back surface side of the semiconductor substrate relative to the drift region and which includes a first peak of a doping concentration and a second peak of the doping concentration which is provided in a front surface side of the semiconductor substrate relative to the first peak, and a first lifetime control region provided between the first peak and the second peak in a depth direction of the semiconductor substrate. An integrated concentration obtained from an upper end of the drift region to the second peak may be a critical integrated concentration or more in the depth direction of the semiconductor substrate.

The contents of the following Japanese patent application(s) are incorporated herein by reference:
NO. 2021-100678 filed in JP on Jun. 17, 2021
NO. PCT/JP2022/024088 filed in WO on Jun. 16, 2022

### BACKGROUND

### 1. Technical Field

The present invention relates to a semiconductor device and a manufacturing method of the semiconductor device.

### 2. Related Art

Patent document 1 describes that “an insulated gate bipolar transistor which is constituted to have a simple lifetime control structure and which has a small tail loss and can perform high speed switching” is provided.

### LIST OF CITED REFERENCES

### Patent Document

Patent Document 1: Japanese Patent Application Publication No. 2011-086883

### Problem to be Solved

An electrical characteristic of a semiconductor device is preferably improved.

### BRIEF DESCRIPTION OF THE DRAWINGS

FIG. 1A illustrates an example of a top view of a semiconductor device 100.

FIG. 1B illustrates an example of a cross section a-a′ in FIG. 1A.

FIG. 2A illustrates an example of a doping concentration distribution in a collector region 22, a buffer region 20, and a drift region 18.

FIG. 2B is an enlarged view of a doping concentration distribution in the vicinity of a first lifetime control region 151.

FIG. 3A illustrates a top view of a modification example of the semiconductor device 100.

FIG. 3B illustrates a cross section b-b′ of the modification example of the semiconductor device 100.

FIG. 4 illustrates an example of a doping concentration distribution in a semiconductor substrate 10.

FIG. 5 is a flowchart illustrating an example of a manufacturing process of the semiconductor device 100.

FIG. 6 illustrates a characteristic of the semiconductor device 100 with respect to a peak depth of the first lifetime control region 151.

FIG. 7 illustrates an example of a doping concentration distribution of a semiconductor device of a comparative example.

FIG. 8 is a graph representing a relationship between a leakage current and a turn-off loss Eoff.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes specify relative positions of components, and do not limit a specific direction. For example, the Z axis is not limited to indicate the height direction with respect to the ground. Note that a +Z axis direction and a −Z axis direction are directions opposite to each other. When the Z axis direction is described without the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. This error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor representing a conductivity type of the N type, or a semiconductor representing a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is referred to as N_{D} and the acceptor concentration is referred to as N_{A}, the net doping concentration at any position is given as N_{D}-N_{A}. In the present specification, the net doping concentration may be simply referred to as the doping concentration.

The donor has a functionality of supplying electrons to a semiconductor. The acceptor has a functionality of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor.

In the present specification, a description of a P+ type or an N+ type means a higher doping concentration than that of the P type or the N type, and a description of a P− type or an N− type described herein means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder of a crystal structure due to a lattice defect or the like.

The concentration of the donor or acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated.

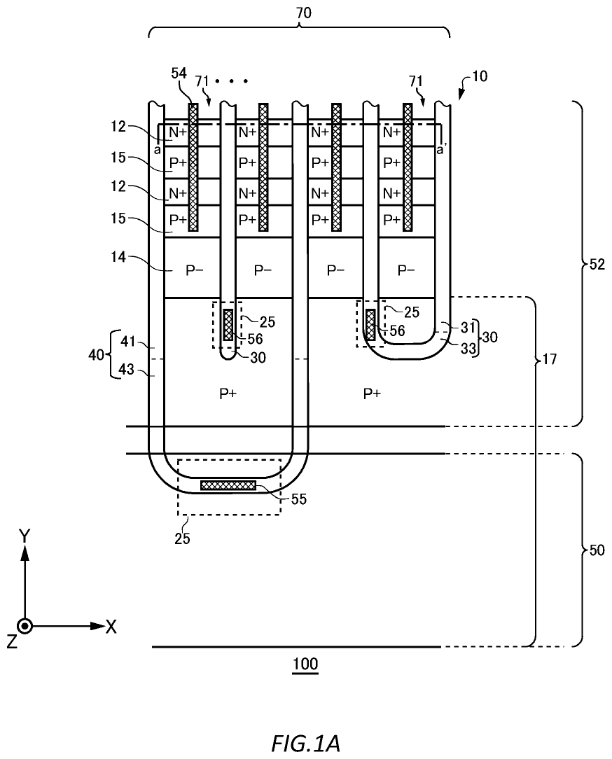

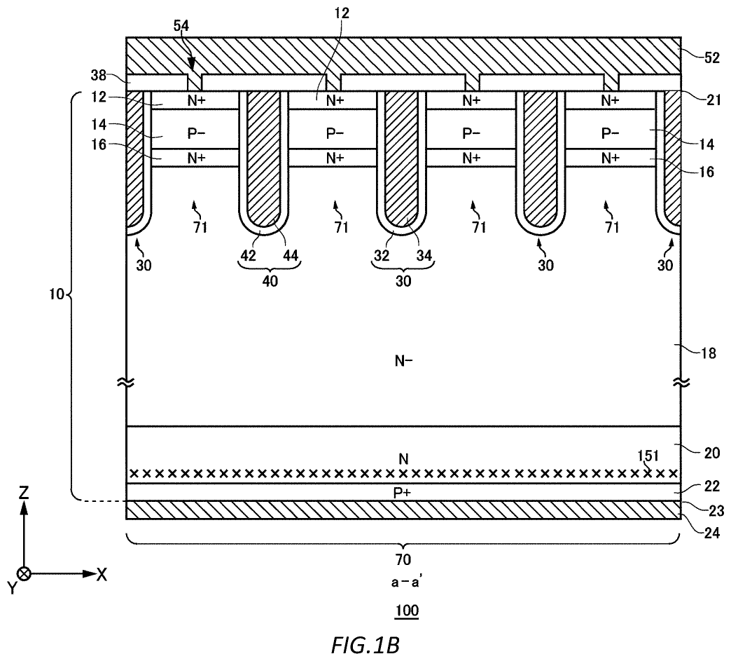

FIG. 1A illustrates an example of the top view of a semiconductor device 100. The semiconductor device 100 in the present example is a semiconductor chip that includes a transistor portion 70.

The transistor portion 70 is a region obtained by projecting a collector region 22 provided in a back surface side of a semiconductor substrate 10 onto an upper surface of the semiconductor substrate 10. The collector region 22 will be described below. The transistor portion 70 includes transistors such as IGBTs.

FIG. 1A illustrates a surrounding region of a chip end portion, which is an edge side of the semiconductor device 100, and the other regions are omitted. For example, an edge termination structure portion may be provided in a region in a negative side of the Y axis direction in the semiconductor device 100 in the present example. The edge termination structure portion is to relax an electric field strength in the upper surface side of the semiconductor substrate 10. The edge termination structure portion includes, for example, a guard ring, a field plate, or a RESURF structure, or combinations thereof. Note that although the present example describes the edge in the negative side in the Y axis direction for convenience, the same applies to other edges of the semiconductor device 100.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 in the present example includes, at a front surface 21 of the semiconductor substrate 10, a gate trench portion 40, a dummy trench portion 30, an emitter region 12, a base region 14, a contact region 15, and a well region 17. The front surface 21 will be described below. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. At least a partial region of the emitter electrode 52 may be formed of metal such as aluminum (Al) or a metal alloy such as an aluminum-silicon alloy (AlSi) and an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may include a barrier metal formed of titanium, titanium compound, or the like, which underlies a region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. A contact hole 54, a contact hole 55, and a contact hole 56 are provided through the interlayer dielectric film 38.

The contact holes 55 connect the gate metal layer 50 and the gate conductive portions inside the transistor portions 70. Inside the contact hole 55, a plug formed of tungsten or the like may be formed.

The contact hole 56 connects the emitter electrode 52 with a dummy conductive portion in a dummy trench portion 30. Inside the contact hole 56, a plug formed of tungsten or the like may be formed.

The connection portion 25 electrically connects a front surface side electrode such as the emitter electrode 52 or the gate metal layer 50 to the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with impurities. The connection portion 25 in the present example is polysilicon doped with an N type impurity (N+). The connection portion 25 is provided above the front surface 21 of the semiconductor substrate 10 via a dielectric film such as an oxide film, or the like.

The gate trench portion 40 is put into an array at a predetermined interval along a predetermined array direction (the X axis direction in the present example). The gate trench portion 40 in the present example may include: two extending segments 41 which extend along an extending direction (the Y axis direction in the present example) parallel to the front surface 21 of the semiconductor substrate 10 and perpendicular to the array direction; and a connecting segment 43 which connects two extending segments 41.

At least a part of the connecting segment 43 is preferably formed in a curved shape. By connecting end portions of the two extending segments 41 of the gate trench portions 40, an electric field strength at the end portions of the extending segments 41 can be reduced. At the connecting segment 43 of the gate trench portion 40, the gate metal layer 50 may be connected to the gate conductive portion.

The dummy trench portion 30 is a trench portion electrically connected to the emitter electrode 52. The dummy trench portion 30 is put into an array, similarly to the gate trench portion 40, at a predetermined interval along a predetermined array direction (the X axis direction in the present example). The dummy trench portion 30 in the present example may have, similarly to the gate trench portion 40, a U shape on the front surface 21 of the semiconductor substrate 10. That is, the dummy trench portion 30 may include two extending segments 31 which extend along the extending direction and a connecting segment 33 which connects two extending segments 31.

The transistor portion 70 in the present example has a repetitive array structure of two gate trench portions 40 and three dummy trench portions 30. That is, the transistor portion 70 in the present example includes the gate trench portions 40 and the dummy trench portions 30 at a ratio of 2:3. For example, the transistor portion 70 includes one extending segment 31 between two extending segments 41. In addition, the transistor portion 70 includes two extending segments 31 adjacent to the gate trench portion 40.

It is noted however that the ratio of the gate trench portions 40 and the dummy trench portions 30 is not limited to the present example. The ratio of the gate trench portions 40 and the dummy trench portions 30 may be 1:1 or may be 2:4. Alternatively, with all trench portions being the gate trench portions 40, the transistor portion 70 does not need to include the dummy trench portion 30.

The well region 17 is a region of a second conductivity type which is provided in a front surface 21 side of the semiconductor substrate 10 relative to a drift region 18 which will be described below. The well region 17 is an example of the well region provided in the edge side of the semiconductor device 100. The well region 17 is of the P+ type as an example. The well region 17 is formed within a predetermined range from an end portion of the active region in a side in which the gate metal layer 50 is provided. A diffusion depth of the well region 17 may be deeper than depths of the gate trench portion 40 and the dummy trench portion 30. Partial regions of the gate trench portion 40 and the dummy trench portion 30 in the gate metal layer 50 side are formed in the well region 17. The bottoms at the end of the extending direction of the gate trench portion 40 and the dummy trench portion 30 may be covered by the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in the extending direction.

A mesa portion 71 is a mesa portion provided adjacent to the trench portion in a plane parallel to the front surface 21 of the semiconductor substrate 10. The mesa portion may be a portion of the semiconductor substrate 10 sandwiched between two trench portions adjacent to each other, and may be a portion ranging from the front surface 21 of the semiconductor substrate 10 to the depth of the lowermost bottom portion of each trench portion. The extending segments of each trench portion may be regarded as one trench portion. That is, the region sandwiched between two extending segments may be set to be a mesa portion.

The mesa portion 71 is provided adjacent to at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. The mesa portion 71 includes the emitter regions 12 and the contact regions 15 alternately provided in the extending direction.

The base region 14 is a region of the second conductivity type which is provided in the front surface 21 side of the semiconductor substrate 10. The base region 14 is of the P− type as an example. The base regions 14 may be provided at both end portions of the mesa portion 71 in the Y axis direction in the front surface 21 of the semiconductor substrate 10. Note that FIG. 1A illustrates only one end portion in the Y axis direction of the base region 14.

The emitter region 12 is a region of the first conductivity type having a higher doping concentration than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one of two trench portions sandwiching the mesa portion 71 to the other of the two trench portions. The emitter region 12 is also provided below the contact hole 54.

In addition, the emitter region 12 may or may not be in contact with the dummy trench portion 30. The emitter region 12 in the present example is in contact with the dummy trench portion 30.

The contact region 15 is a region of the second conductivity type having a higher doping concentration than that of the base region 14. The contact region 15 in the present example is of the P+ type as an example. The contact region 15 in the present example is provided in the front surface 21 of the mesa portion 71. The contact region 15 may be provided in the X axis direction from one of two trench portions sandwiching the mesa portion 71 to the other of the two trench portions. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1B illustrates an example of a cross section a-a′ in FIG. 1A. The cross section a-a′ is an XZ plane which extends through the emitter region 12 in the transistor portion 70. In the cross section a-a′, the semiconductor device 100 in the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region of the first conductivity type which is provided in a back surface 23 side of the semiconductor substrate 10 relative to the drift region 18. The buffer region 20 in the present example is of the N type as an example. The doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type.

The collector region 22 is provided below the buffer region 20 in the transistor portion 70. The collector region 22 has the second conductivity type. The collector region 22 in the present example is of the P+ type as an example.

The collector electrode 24 is formed at a back surface 23 of the semiconductor substrate 10. The collector electrode 24 is formed of a conductive material such as metal.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided between the base region 14 and the front surface 21. The emitter region 12 is provided in contact with the gate trench portion 40. The emitter region 12 may or may not be in contact with the dummy trench portion 30.

The accumulation region 16 is a region of the first conductivity type which is provided in the front surface 21 side of the semiconductor substrate 10 relative to the drift region 18. The accumulation region 16 in the present example is of the N+ type as an example. It is noted however that the accumulation region 16 may not be provided.

In addition, the accumulation region 16 is provided in contact with the gate trench portion 40. The accumulation region 16 may be or may not be in contact with the dummy trench portion 30. The doping concentration of the accumulation region 16 is higher than the doping concentration of the drift region 18. An ion implantation dose amount of the accumulation region 16 may be 1.0 E12 cm⁻² or more and 1.0 E13 cm⁻² or less. Alternatively, the ion implantation dose amount of the accumulation region 16 may be 3.0 E12 cm⁻² or more and 6.0 E12 cm⁻² or less. Providing the accumulation region 16 can enhance the carrier injection enhancement effect (IE effect) to reduce an ON voltage of the transistor portion 70. Note that E means a power of 10, and, for example, 1.0 E12 cm⁻² means 1.0×10¹² cm⁻².

One or more gate trench portions 40 and one or more dummy trench portions 30 are provided at the front surface 21. Each trench portion is provided from the front surface 21 to the drift region 18. For regions provided with at least any of the emitter region 12, the base region 14, the contact region 15, or the accumulation region 16, each trench portion also passes through these regions to reach the drift region 18. The configuration of the trench portion passing through the doping region is not limited to that manufactured in the order of forming the doping region and then forming the trench portion. The configuration of the trench portion passing through the doping region also includes a configuration of the doping region being formed between the trench portions after forming the trench portions.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate dielectric film 42 is formed in the interior of the gate trench, and the gate conductive portion 44 is formed inside the gate dielectric film 42. The gate dielectric film 42 is configured to insulate the gate conductive portion 44 and the semiconductor substrate 10. The gate conductive portion 44 is formed of a conductive material such as polysilicon. The gate trench portion 40 is covered by the interlayer dielectric film 38 in the front surface 21.

The gate conductive portion 44 includes a region opposing the adjacent base region 14 in the mesa portion 71 side by sandwiching the gate dielectric film 42 in a depth direction of the semiconductor substrate 10. When a predetermined voltage is applied to the gate conductive portion 44, a channel is formed at a surface layer being at a boundary within the base region 14 and in direct contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are formed in the front surface 21 side. The dummy dielectric film 32 is formed covering the inner walls of the dummy trench. The dummy conductive portion 34 is formed in the interior of the dummy trench and also formed inside the dummy dielectric film 32. The dummy dielectric film 32 insulates the dummy conductive portion 34 from the semiconductor substrate 10. The dummy trench portion 30 is covered by the interlayer dielectric film 38 in the front surface 21.

The interlayer dielectric film 38 is provided at the front surface 21. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to pass through the interlayer dielectric film 38.

A first lifetime control region 151 is a region in which a lifetime killer is intentionally formed by, for example, implantation of impurities into the inside of the semiconductor substrate 10. As an example, the first lifetime control region 151 is formed by implanting helium into the semiconductor substrate 10. By providing the first lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements configuring the semiconductor substrate 10, or dislocation. Furthermore, the lifetime killer may be a noble gas element such as helium and neon, a metal element such as platinum, or the like. An electron beam may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. Alternatively, the lifetime killer concentration may be a chemical concentration of the noble gas element such as helium and neon, or may be a chemical concentration of the metal element such as platinum.

The first lifetime control region 151 is provided in the back surface 23 side relative to the center of the semiconductor substrate 10 in the depth direction of the semiconductor substrate 10. The first lifetime control region 151 in the present example is provided in the buffer region 20. The first lifetime control region 151 in the present example is provided at an entire surface of the semiconductor substrate 10 in the XY plane, and can be formed without using a mask. The first lifetime control region 151 may be provided in a part of the semiconductor substrate 10 in the XY plane. A dose amount of impurities for forming the first lifetime control region 151 may be 0.5 E10 cm⁻² or more and 1.0 E13 cm⁻² or less, or may be 5.0 E10 cm⁻² or more and 5.0 E11 cm⁻² or less.

In addition, the first lifetime control region 151 in the present example is formed by the implantation from the back surface 23 side. With this configuration, an impact in the front surface 21 side of the semiconductor device 100 can be avoided. For example, the first lifetime control region 151 is formed by irradiating helium from the back surface 23 side. Herein, which of the front surface 21 side and the back surface 23 side the implantation is performed from for forming the first lifetime control region 151 can be determined by acquiring a state of the front surface 21 side by an SRP method or a measurement of a leakage current.

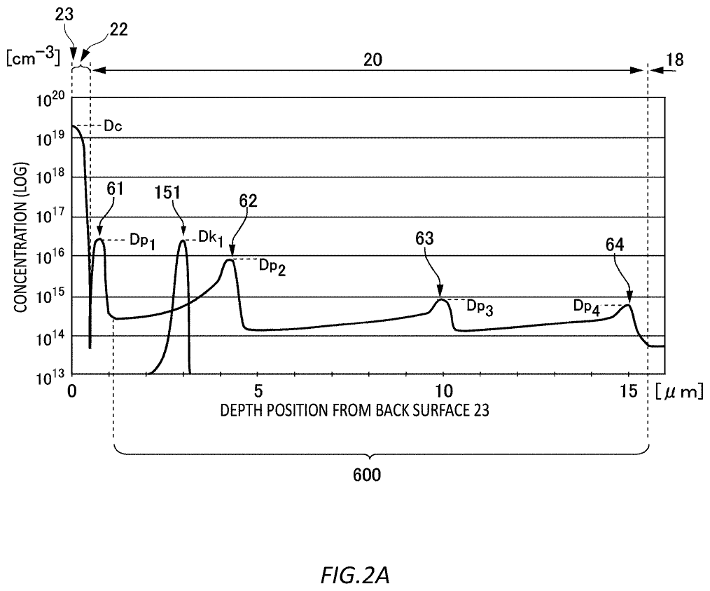

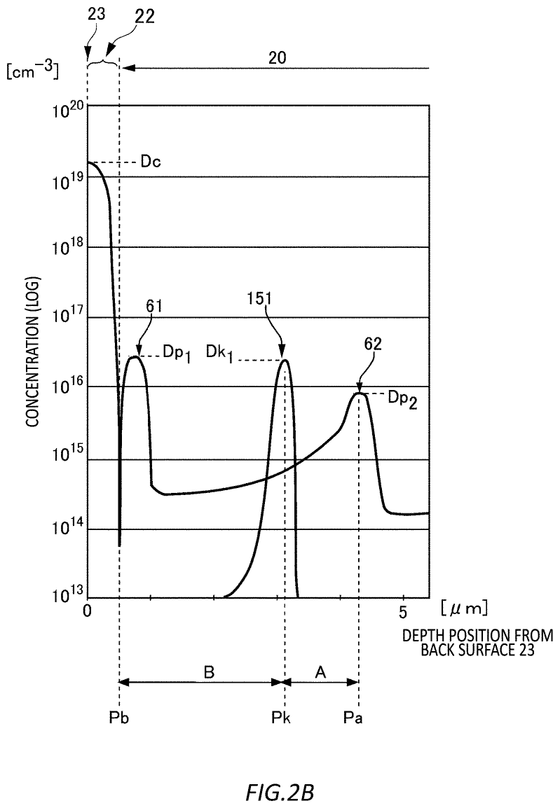

FIG. 2A illustrates an example of a doping concentration distribution in the collector region 22, the buffer region 20, and the drift region 18. The present drawing illustrates a distribution of a lifetime killer concentration of the first lifetime control region 151 too. In the present example, the lifetime killer concentration of the first lifetime control region 151 is a helium concentration.

Note that the doping concentration distribution in the collector region 22, the buffer region 20, and the drift region 18 represents a net doping concentration obtained by taking each impurity concentration together except for one in the first lifetime control region 151.

The buffer region 20 has peaks with a plurality of doping concentrations. The buffer region 20 in the present example has four peaks including a first peak 61, a second peak 62, a third peak 63, and a fourth peak 64. A lower end of the buffer region 20 may be a boundary between the collector region 22 and the first peak 61. An upper end of the buffer region 20 may be a boundary between the fourth peak 64 and the drift region 18. A thickness in a depth direction of the buffer region 20 may be 10.0 μm or more and 30.0 μm or less. Note that in the present specification, a position of each of the peaks is a position at which the doping concentration shows a local maximum.

The first peak 61 is provided in the front surface 21 side relative to the collector region 22. The first peak 61 is a peak closest to the back surface 23 among the plurality of peaks included in the buffer region 20. The first peak 61 may be provided at a depth position of 0.5 μm or more and 2.0 μm or less from the back surface 23. For example, the depth position of the first peak 61 from the back surface 23 is 0.7 μm. The depth position refers to a position from the back surface 23 in the depth direction of the semiconductor substrate 10.

The first peak 61 may be a peak with a highest doping concentration in the buffer region 20. The doping concentration at the first peak 61 may be 1.0 E15 cm⁻³ or more, and may be 1.0 E16 cm⁻³ or more. The doping concentration at the first peak 61 may be 1.0 E17 cm⁻³ or less, and may be 5.0 E16 cm⁻³ or less. For example, the doping concentration at the first peak 61 is 2.0 E16 cm⁻³. A dopant of the first peak 61 may be phosphorus, arsenic, or hydrogen. In the present example, the dopant of the first peak 61 is phosphorus.

The second peak 62 is provided in the front surface 21 side relative to the first peak 61. The second peak 62 may be provided at a depth position of 2.0 μm or more and 7.0 μm or less from the back surface 23. For example, the depth position of the second peak 62 from the back surface 23 is 4.0 μm. The doping concentration at the second peak 62 may be 1.0 E15 cm⁻³ or more, and may be 3.0 E15 cm⁻³ or more. The doping concentration at the second peak 62 may be 2.0 E16 cm⁻³ or less, and may be 1.0 E16 cm⁻³ or less. The doping concentration at the second peak 62 in the present example is 5.0 E15 cm⁻³ or more.

The third peak 63 is provided in the front surface 21 side relative to the second peak 62. The third peak 63 may be provided at a depth position of 7.0 μm or more and 13.0 μm or less from the back surface 23. For example, the depth position of the third peak 63 from the back surface 23 is 10.0 μm.

The fourth peak 64 is provided in the front surface 21 side relative to the third peak 63. The fourth peak 64 may be provided at a depth position that is 10% or more and 20% or less of a substrate thickness of the semiconductor substrate 10 from the back surface 23. For example, the depth position of the fourth peak 64 from the back surface 23 is 15.0 μm.

Each peak of the buffer region 20 may be formed by a same dopant, or may be formed by different dopants. The dopant of each peak of the buffer region 20 may be hydrogen. The first peak 61 may be formed by phosphorus ion implantation, and other peaks may be formed by ion implantation of hydrogen ions. Hydrogen ions may be proton, deuteron, or triton. Hydrogen ions in the present example are proton. Alternatively, the dopant of the first peak 61 may be phosphorus, and the dopant of other peaks may be hydrogen.

The doping concentration at the first peak 61 may be higher than the doping concentrations of the peaks other than the first peak 61. The doping concentration at the first peak 61 may be lower than a maximum value of the doping concentration of the collector region 22. The doping concentration at the first peak 61 may be determined such that a hole concentration or hole current implanted from the collector region 22 in a state where a gate is on is to be adjusted.

The doping concentrations at the peaks other than the first peak 61 in the buffer region 20 may decrease towards the front surface 21 side. Alternatively, the doping concentration at a peak closest to the front surface 21 side among the peaks other than the first peak 61 may be higher than, or may be equal to, the doping concentration at an adjacent peak in the back surface 23 side of the peak. In the present example, the peak closest to the front surface 21 side is the fourth peak 64, and the adjacent peak in the back surface 23 side of the fourth peak 64 is the third peak 63. A doping concentration Dp₄ of the fourth peak 64 may be lower than, may be the same as, or may be higher than, a doping concentration Dp₃ of the third peak 63. In the present example, the doping concentration Dp₄ is lower than the doping concentration Dp₃.

A number of at least one peak of the buffer region 20 may be four or more. That is, the number of peaks of the buffer region 20 may be five, may be six, or may be seven or more.

The first lifetime control region 151 is provided between the first peak 61 and the second peak 62 in the depth direction of the semiconductor substrate 10. With this configuration, while an increase in a leakage current is suppressed, a turn-off loss Eoff is likely to be reduced. The first lifetime control region 151 may be provided at a depth position of 1.0 μm or more and 4.0 μm or less from the back surface 23. The first lifetime control region 151 may have a single peak or may have a plurality of peaks in a lifetime killer concentration distribution. The lifetime killer concentration distribution of the first lifetime control region 151 in the present example is a helium chemical concentration distribution having a single peak.

FIG. 2B is an enlarged view of the lifetime killer concentration distribution in the vicinity of the first lifetime control region 151. The present drawing illustrates doping concentrations of the collector region 22, the first peak 61, the second peak 62, and the first lifetime control region 151.

A depth position Pk represents a depth position of the peak of the first lifetime control region 151 from the back surface 23. A depth position Pa represents a depth position of the second peak 62 from the back surface 23. A depth position Pb represents a depth position of an upper end of the collector region 22 from the back surface 23. The upper end of the collector region 22 refers to a surface of the collector region 22 in the front surface 21 side. The depth position Pb represents a thickness in the depth direction of the collector region 22. The thickness in the depth direction of the collector region 22 may be 0.2 μm or more and 1.0 μm or less from the back surface 23.

A distance A is a distance between the second peak 62 and the peak of the doping concentration of the first lifetime control region 151 in the depth direction of the semiconductor substrate 10. That is, the distance A is calculated by Pa−Pk. With the provision of the distance A, disappearance of a lattice defect of the first lifetime control region 151 can be suppressed. The distance A may be 0.2 μm or more, and may be 0.5 μm or more.

A distance B is a distance between the upper end of the collector region 22 and the peak of the first lifetime control region 151 in the depth direction of the semiconductor substrate 10. That is, the distance B is calculated by Pk−Pb. With the provision of the distance B, the disappearance of the lattice defect of the first lifetime control region 151 can be suppressed. The distance B may be 0.1 μm or more, and may be 1.0 μm or more.

Herein, the distance A may be smaller than the distance B. That is, the peak of the first lifetime control region 151 may be arranged to be on a side closer to the second peak 62 between the depth position Pa and the depth position Pb. The distance A may be ½ or less, or may be ⅓ or less, of the distance B. Note that the distance A may be larger than the distance B. The distance A may be two times or more, or may be three times or more the distance B.

The lifetime killer concentration distribution of the first lifetime control region 151 may include a peak concentration Dk₁ and a full width at half maximum (FWHM) of the peak concentration Dk₁. By setting the full width at half maximum of the peak concentration Dk₁ to be small, an impact to the peak of the adjacent buffer region 20 can be reduced. That is, by setting the full width at half maximum of the first lifetime control region 151 to be still smaller, the disappearance of the lattice defect of the first lifetime control region 151 can be suppressed. For example, the full width at half maximum of the first lifetime control region 151 is 0.5 μm or less.

The peak of the lifetime killer concentration of the first lifetime control region 151 may be positioned at a depth of 0.6 μm or more and 3.8 μm or less from the back surface of the semiconductor substrate 10. By setting the depth position of the first lifetime control region 151 to be deep, the turn-off loss Eoff is likely to be reduced. It is noted however that when the depth position of the first lifetime control region 151 is set to be too deep, the first lifetime control region may be connected to the depletion layer extending from the lower surface side of the base region 14, and the leakage current may increase.

In addition, the peak concentration Dk₁ of the lifetime killer concentration of the first lifetime control region 151 may be larger than a peak concentration Dp₁ of the doping concentration at the first peak 61. The peak concentration Dk₁ of the lifetime killer concentration of the first lifetime control region 151 may be two times or more, may be five times or more, or may be ten times or more that at the first peak 61. In an example, the peak concentration Dk₁ of the lifetime killer concentration of the first lifetime control region 151 is 1.0 E15 cm⁻³ or more and 1.0 E17 cm⁻³ or less.

By setting the peak concentration Dk₁ of the lifetime killer concentration of the first lifetime control region 151 to be larger than the peak concentration Dp₁ of the doping concentration at the first peak 61, the following advantage is attained. Hydrogen for forming the buffer region 20 terminates a dangling bond of the lattice defect in the vicinity of the peak concentration of the buffer region 20. With this configuration, the introduced lattice defect may disappear. Even when the lattice defect disappears in the vicinity of the peak concentration of the buffer region 20, in a case where the peak concentration Dk₁ of the lifetime killer concentration of the first lifetime control region 151 is higher than the peak concentration of the buffer region 20, the disappearance of the lattice defect is suppressed. With this configuration, an excess carrier in the back surface 23 side at the time of a reverse recovery operation can be sufficiently decreased.

The peak concentration Dk₁ of the lifetime killer concentration at the peak of the first lifetime control region 151 is smaller than a peak concentration Dc of the doping concentration of the collector region 22. The doping concentration at the peak of the collector region 22 may be 1.0 E17 cm⁻³ or more and 1.0 E19 cm⁻or less.

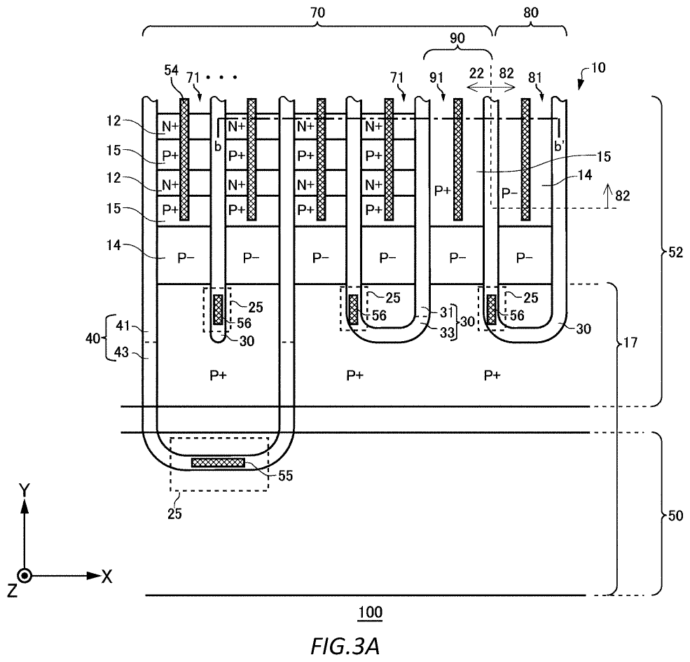

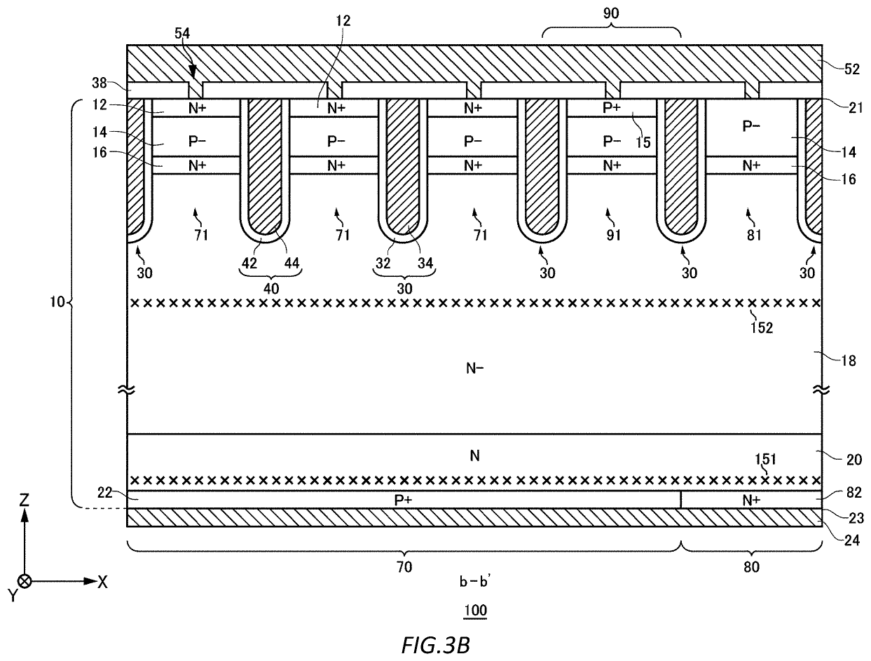

FIG. 3A illustrates a top view of a modification example of the semiconductor device 100. The semiconductor device 100 in the present example includes the transistor portion 70 and a diode portion 80. For example, the semiconductor device 100 is a reverse conducting IGBT (RC-IGBT). The transistor portion 70 in the present example includes a boundary portion 90 that is positioned at a boundary between the transistor portion 70 and the diode portion 80.

The diode portion 80 is a region obtained by projecting a cathode region 82 provided in the back surface side of the semiconductor substrate 10 onto the upper surface of the semiconductor substrate 10. The cathode region 82 has the first conductivity type. The cathode region 82 in the present example is of the N+ type as an example. The diode portion 80 includes a diode such as a free wheel diode (FWD) provided being adjacent to the transistor portion 70 at the upper surface of the semiconductor substrate 10.

The boundary portion 90 is a region provided in the transistor portion 70, and is adjacent to the diode portion 80. The boundary portion 90 includes the contact region 15. The boundary portion 90 in the present example does not include the emitter region 12. In an example, the trench portions in the boundary portion 90 are the dummy trench portions 30. The boundary portion 90 in the present example includes the trench portions the dummy trench portions 30 of which are arranged at the both ends in the X axis direction.

The contact hole 54 is provided above the base region 14 in the diode portion 80. The contact hole 54 is provided above the contact region 15 in the boundary portion 90. No contact holes 54 are provided above the well regions 17 provided at the both ends in the Y axis direction.

The mesa portion 91 is provided in the boundary portion 90. The mesa portion 91 includes the contact region 15 in the front surface 21 of the semiconductor substrate 10. The mesa portion 91 in the present example includes the base region 14 and the well region 17 in the negative direction of the Y axis.

The mesa portion 81 is provided in a region sandwiched between the dummy trench portions 30 adjacent to each other in the diode portion 80. The mesa portion 81 includes the base region 14 in the front surface 21 of the semiconductor substrate 10. The mesa portion 81 in the present example includes the base region 14 and the well region 17 in the negative direction of the Y axis.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81.

FIG. 3B illustrates a cross section b-b′ of a modification example of the semiconductor device 100. The semiconductor device 100 in the present example includes the first lifetime control region 151 and a second lifetime control region 152.

The contact region 15 is provided above the base region 14 in the mesa portion 91. The contact region 15 is provided in contact with the dummy trench portion 30 in the mesa portion 91. In another cross section, the contact region 15 may be provided at the front surface 21 in the mesa portion 71.

The accumulation region 16 is provided in the transistor portion 70 and the diode portion 80. The accumulation region 16 in the present example is provided at entire surfaces of the transistor portion 70 and the diode portion 80. It is to be noted that the accumulation region 16 does not need to be provided in the diode portion 80.

The cathode region 82 is provided below the buffer region 20 in the diode portion 80. The boundary between the collector region 22 and the cathode region 82 is a boundary between the transistor portion 70 and the diode portion 80. That is, the collector region 22 is provided below the boundary portion 90 in the present example.

The first lifetime control region 151 is provided in both the transistor portion 70 and the diode portion 80. With this configuration, in the semiconductor device 100 in the present example, a recovery speed in the diode portion 80 can be raised, and a switching loss can be further improved. The first lifetime control region 151 may be formed by a method similar to that of the first lifetime control region 151 in other examples.

The second lifetime control region 152 is provided in the front surface 21 side relative to the center of the semiconductor substrate 10 in the depth direction of the semiconductor substrate 10. The second lifetime control region 152 in the present example is provided in the drift region 18. The second lifetime control region 152 is provided in both the transistor portion 70 and the diode portion 80. The second lifetime control region 152 may be formed by implanting an impurity from the front surface 21 side, or may be formed by implanting an impurity from the back surface 23 side. The second lifetime control region 152 may be provided in the diode portion 80 and the boundary portion 90, and does not need to be provided in a part of the transistor portion 70.

The second lifetime control region 152 may be formed by any method among the methods for forming the first lifetime control region 151. Elements, dose amounts, and the like for forming the first lifetime control region 151 and the second lifetime control region 152 may be the same or may be different.

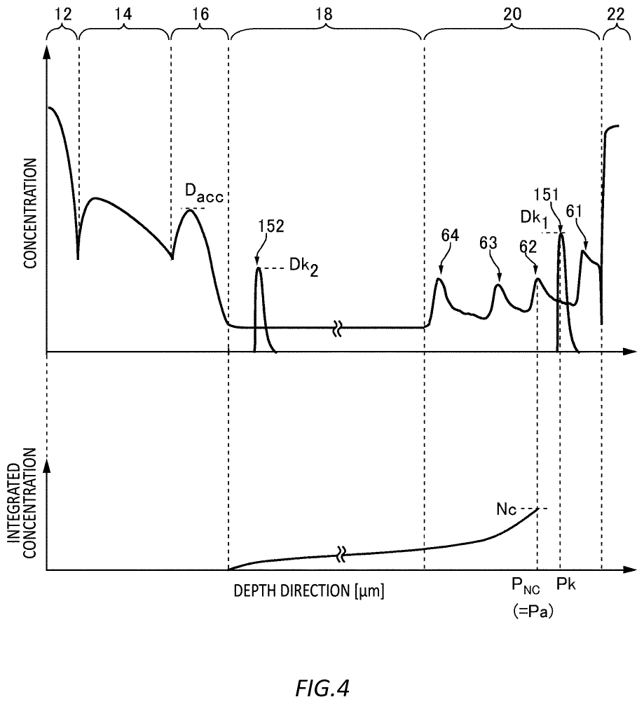

FIG. 4 illustrates an example of a doping concentration distribution in the semiconductor substrate 10. The present drawing illustrates a distribution of doping concentrations of the first lifetime control region 151 and the second lifetime control region 152 too. In addition, the present drawing illustrates an integrated concentration from an upper end of the drift region 18 too.

In the present specification, a value obtained by integrating the doping concentration from the lower surface side of the base region 14 to a particular position of the semiconductor substrate 10 along the depth direction of the semiconductor substrate 10 is referred to as an integrated concentration. In addition, in the present specification, in a case where a forward bias is applied between the collector electrode 24 and the emitter electrode 52 and a maximum value of an electric field intensity has reached a critical electric field intensity so that avalanche breakdown has occurred and also in a case where a section from the lower surface of the base region 14 to the particular position of the semiconductor substrate 10 in the depth direction is depleted, it is called that the integrated concentration has reached the critical integrated concentration Nc. Note that in the semiconductor device 100, the application of the forward bias between the collector electrode 24 and the emitter electrode 52 refers to a situation where a potential of the collector electrode 24 is higher than a potential of the emitter electrode 52 in a state where the gate is off. When avalanche breakdown has occurred in the semiconductor device 100, an avalanche current flows between the collector electrode 24 and the emitter electrode 52, and an increase in a voltage V_{CE} between the collector electrode 24 and the emitter electrode 52 stops. In this case, the depletion layer does not extend onto the back surface side relative to the position P_{Nc} at which the integrated concentration reaches the critical integrated concentration Nc.

The first lifetime control region 151 in the present example is provided in the back surface 23 side relative to the second peak 62. The integrated concentration from the upper end of the drift region 18 to the second peak 62 may be the critical integrated concentration Nc or more in the depth direction of the semiconductor substrate 10. The position P_{Nc} at which the integrated concentration reaches the critical integrated concentration Nc may match the position Pa of the second peak 62. With this configuration, since the depletion layer extending from the lower surface side of the base region 14 is stopped by the second peak 62, the peak of the first lifetime control region 151 can be arranged in a region that is not to be depleted. Accordingly, the increase in the leakage current due to the implantation of the first lifetime control region 151 can be suppressed. Note that the integrated concentration from the upper end of the drift region 18 to the third peak 63 may be less than the critical integrated concentration Nc in the depth direction of the semiconductor substrate 10. That is, the depletion layer extending from the lower surface side of the base region 14 may be stopped by the second peak 62.

A configuration may be adopted where the position P_{Nc} at which the integrated concentration reaches the critical integrated concentration Nc does not match the peak position (peak Pa in the present example) of the buffer region 20. The position P_{Nc} at which the integrated concentration reaches the critical integrated concentration Nc may be positioned between the position Pa of the second peak 62 and the third peak 63. The position P_{Nc} at which the integrated concentration reaches the critical integrated concentration Nc may be positioned at the position of the third peak 63. The position P_{Nc} at which the integrated concentration reaches the critical integrated concentration Nc may be positioned between the fourth peak 64 and the third peak 63. The position P_{Nc} at which the integrated concentration reaches the critical integrated concentration Nc may be positioned at the position of the fourth peak 64.

A peak concentration Dk₂ of the lifetime killer concentration of the second lifetime control region 152 may be smaller than, may be equal to, or may be larger than, the peak concentration Dk₁ of the lifetime killer concentration of the first lifetime control region 151. In the present example, the peak concentration Dk₂ of the second lifetime control region 152 is smaller than the peak concentration Dk₁ of the first lifetime control region 151. The peak concentration Dk₂ of the second lifetime control region 152 may be smaller than, may be equal to, or may be larger than, a peak concentration D_{acc} of the doping concentration of the accumulation region 16. In the present example, the peak concentration Dk₂ of the second lifetime control region 152 is smaller than the peak concentration D_{acc} of the accumulation region 16. The peak concentration Dk₂ of the second lifetime control region 152 may be larger than, may be equal to, or may be smaller than, a peak concentration Dp₄ of the doping concentration of the fourth peak 64. In the present example, the peak concentration Dk₂ of the second lifetime control region 152 is larger than the peak concentration Dp₄ of the doping concentration of the fourth peak 64.

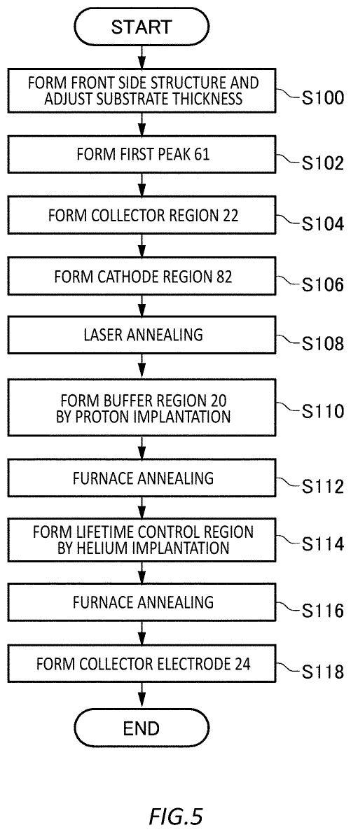

FIG. 5 is a flowchart illustrating an example of a manufacturing process of the semiconductor device 100. In step S100, a structure in the front surface side of the semiconductor device 100 is formed. In addition, in step S100, after the structure in the front surface side has been formed, the back surface 23 side of the semiconductor substrate 10 is ground to adjust the thickness of the semiconductor substrate 10 according to a demanded breakdown voltage.

In step S102, the first peak 61 is formed by ion implantation from the back surface 23 side of the semiconductor substrate 10. In an example, a dopant of the first peak 61 is phosphorus. For example, a dose amount of the dopant of the first peak 61 may be 1.0 E12 cm⁻² or more, and may be 2.0 E12 cm⁻² or more. The dose amount of the dopant of the first peak 61 may be 1.0 E13 cm⁻² or less, and may be 5.0 E12 cm⁻² or less. In the present example, the dose amount thereof is 3.0 E12 cm⁻². The acceleration energy of the dopant of the first peak 61 may be 500 keV or more, and may be 700 keV or more. The acceleration energy of the dopant of the first peak 61 may be 4000 keV or less, and may be 3000 keV or less. In the present example, the acceleration energy thereof is 2000 keV.

In step S104, the collector region 22 is formed. The collector region 22 may be formed at an entire surface of the back surface 23 of the semiconductor substrate 10. The ion dose amount for forming the collector region 22 may be 2.0 E13/cm² or more, and may be 5.0 E13/cm² or less. In addition, the ion dose amount for forming the collector region 22 may be ten times or more and 50 times or less the ion dose amount for forming the first peak 61.

In step S106, the cathode region 82 is formed. Note that after the cathode region 82 has been formed, the collector region 22 may be formed. When the semiconductor device 100 does not have the diode portion 80, step S106 may be omitted. In step S108, a region implanted with an impurity from the back surface 23 side of the semiconductor substrate 10 is heated by laser annealing.

In step S110, the buffer region 20 is formed by ion implantation of hydrogen ions. When a plurality of peaks is formed in the buffer region 20, hydrogen ions are implanted multiple times with different acceleration energy. For example, in step S110, the second peak 62, the third peak 63, and the fourth peak 64 are formed.

As an example, the dose amount of hydrogen ions corresponding to the second peak 62 is 7.0×1012/cm², and the acceleration energy is 1100 keV. The dose amount of hydrogen ions corresponding to the third peak 63 is 1.0×1013/cm², and the acceleration energy is 820 keV. The dose amount of hydrogen ions corresponding to the fourth peak 64 is 3.0×10¹⁴/cm², and the acceleration energy is 400 keV. In step S112, the semiconductor substrate 10 is heated in an annealing furnace of a nitrogen atmosphere or the like. As an example, an annealing temperature is 370 degrees, and an annealing time period is five hours.

In step S114, the first lifetime control region 151 is formed by helium ion implantation from the back surface 23 side of the semiconductor substrate 10. The ion dose amount for forming the first lifetime control region 151 may be 1.0 E11 cm⁻² or more, and may be 3.0 E11 cm⁻² or more. The ion dose amount for forming the first lifetime control region 151 may be 5.0 E12 cm⁻² or less, and may be 2.0 E12 cm⁻² or less. By setting the dose amount of the first lifetime control region 151 to be larger than a predetermined lower limit, the turn-off loss Eoff can be reduced. It is noted however that when the dose amount of the first lifetime control region 151 is set to be larger than a predetermined upper limit, a fluctuation of characteristics due to the lattice defect may occur.

The ion dose amount for forming the collector region 22 may be 300 times or more and 500 times or less the ion dose amount for forming the first lifetime control region 151. The acceleration energy for forming the first lifetime control region 151 may be 50 keV or more, and may be 2000 keV or less. As an example, He²⁺ is implanted at the dose amount of 2×10¹²/cm² and the acceleration energy of 700 keV. In step S116, the semiconductor substrate 10 is heated in an annealing furnace of a nitrogen atmosphere or the like.

Note that the ion dose amount for forming the first lifetime control region 151 may be 0.1 times or more and ten times or less, may be 0.5 times or more and five times or less, or may be 0.7 times or more and three times or less the ion dose amount for forming the first peak 61.

In step S118, the collector electrode 24 is formed. For example, the collector electrode 24 is formed by spattering method. The collector electrode 24 may be a stack electrode in which an aluminum layer, a titanium layer, a nickel layer, and the like are stack. In accordance with such a process, the semiconductor device 100 can be manufactured.

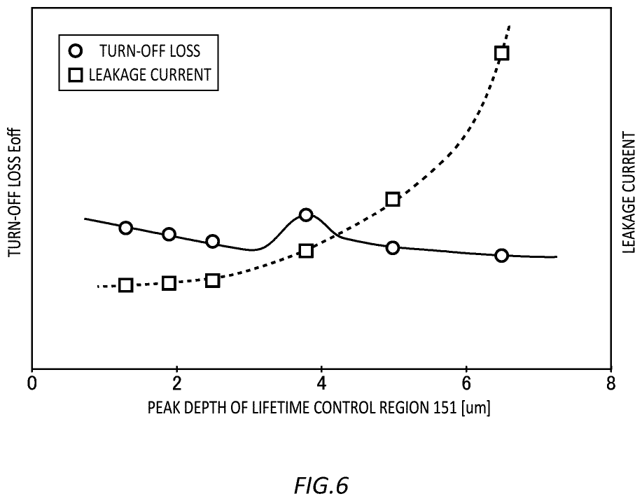

FIG. 6 illustrates a characteristic of the semiconductor device 100 with respect to a peak depth of the first lifetime control region 151. The present drawing illustrates a variation of the turn-off loss Eoff and a variation of the leakage current at the time of application of an IGBT rated voltage with respect to the peak depth of the first lifetime control region 151. As the peak depth of the first lifetime control region 151 is increased, the turn-off loss Eoff tends to be reduced. On the other hand, when the peak depth of the first lifetime control region 151 is set to be too large, the first lifetime control region 151 may be connected to the depletion layer extending from the lower surface side of the base region 14, and the leakage current may increase.

In FIG. 6, FIG. 2A, FIG. 2B, or FIG. 4, when a peak position Pk of the lifetime killer concentration of the first lifetime control region 151 is 4.0 μm from the back surface 23, the turn-off loss Eoff specifically increases. When the peak position Pk is 4.0 μm, the peak position Pk matches the position Pa of the second peak 62 of the buffer region 20. Thus, the lifetime killer concentration distribution of the first lifetime control region 151 overlaps the doping concentration distribution of the second peak 62. With the distributions overlapped, the dangling bond in the vacancy of the first lifetime control region 151 is terminated by hydrogen in the second peak 62 of the buffer region 20. With this configuration, since the peak concentration Dk of the lifetime killer concentration of the first lifetime control region 151 falls, the turn-off loss Eoff increases.

The buffer region 20 may have the first peak 61 and an auxiliary peak group 600. The auxiliary peak group 600 is one or more peaks that are other than the first peak 61 and provided in the front surface 21 side of the semiconductor substrate 10 relative to the first peak 61. In the present example, the auxiliary peak group 600 includes the second peak 62, the third peak 63, and the fourth peak 64. The position P_{Nc} at which the integrated concentration reaches the critical integrated concentration Nc may be at the auxiliary peak group 600. The first lifetime control region 151 may be provided in the auxiliary peak group 600.

The peak position Pk of the first lifetime control region 151 may be away by 0.1 μm or more, may be away by 0.5 μm or more, or may be away by 1.0 μm or more, towards the back surface 23 side from the position P_{Nc} at which the integrated concentration reaches the critical integrated concentration Nc. The peak position Pk may be positioned at a depth of 3.0 μm or less, or may be positioned at a depth of 2.0 μm or less, from the position P_{Nc} towards the back surface 23 side. In the present example, the position P_{Nc} is the position Pa, and the peak position Pk is positioned at a depth away from the position P_{Nc} or the position Pa towards the back surface 23 side by 1 μm.

The position P_{Nc} may be positioned in a range of a full width at half maximum FWHM of a peak concentration Dpx at one peak x among the auxiliary peak group 600. In the present example, the peak x is the second peak 62. The second peak 62 is adjacent to the front surface 21 side of the semiconductor substrate 10 of the first peak 61. Furthermore, a full width at 30% of the peak concentration Dpx at the peak x may be referred to as a 30% full width (FW30% M), and the position P_{Nc} may be positioned in a range of the 30% full width. Furthermore, a full width at 20% of the peak concentration Dpx at the peak x may be referred to as a 20% full width (FW20% M), and the position P_{Nc} may be positioned in a range of the 20% full width. Furthermore, a full width at 10% of the peak concentration Dpx at the peak x may be referred to as a 10% full width (FW10% M), and the position P_{Nc} may be positioned in a range of the 10% full width.

That is, the one peak x among the auxiliary peak group 600 includes the position P_{Nc} at which the integrated concentration becomes the critical integrated concentration Nc in a range of the full width at half maximum, 30% full width, 20% full width, or 10% full width of the peak x. In these cases, the peak concentration Dpx of the peak x may be 3.0 E15 cm⁻³ or more, may be 4.0 E15 cm⁻³ or more, or may be 5.0 E15 cm⁻³ or more. The peak concentration Dpx may be 1.0 E16 cm⁻³ or less, may be 8.0 E15 cm⁻³ or less, or may be 6.0 E15 cm⁻³ or less. In the present example, the peak x is the second peak 62, and Dpx is Dp₂ and is 7.0 E15 cm⁻³. The doping concentration of each peak x of the auxiliary peak group 600 may be smaller than the doping concentration at the first peak 61.

Furthermore, the position Pk of the first lifetime control region 151 may be away by 0.1 μm or more, may be away by 0.5 μm or more, or may be away by 1.0 μm or more, towards the back surface 23 side from the position Px at the peak x which includes the position P_{Nc} in the FWHM, FW30% M, FW20% M, or FW10% M. The peak position Pk may be positioned at a depth of 3.0 μm or less, or may be positioned at a depth of 2.0 μm or less, from the position P_{Nc} towards the back surface 23 side.

Furthermore, the position Pk of the first lifetime control region 151 may be away by 0.1 μm or more, may be away by 0.5 μm or more, or may be away by 1.0 μm or more, towards the back surface 23 side from the position P_{Nc} at the peak x which includes the position P_{Nc} in the FWHM, FW30% M, FW20% M, or FW10% M. The peak position Pk may be positioned at a depth of 3.0 μm or less, or may be positioned at a depth of 2.0 μm or less, from the position P_{Nc} towards the back surface 23 side.

In accordance with the above described configuration, the leakage current can also be reduced while the turn-off loss Eoff can be reduced, and trade-off between the turn-off loss Eoff and the leakage current can be improved.

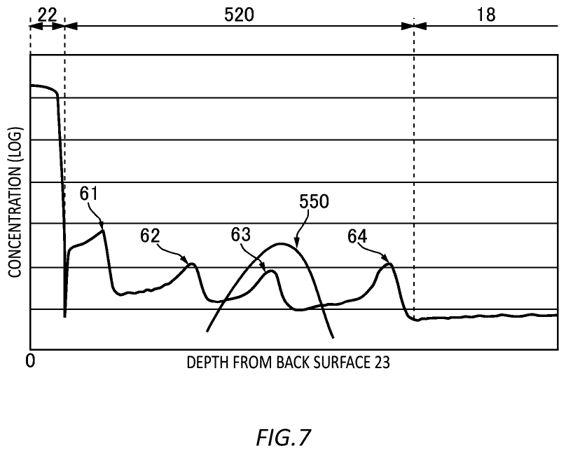

FIG. 7 illustrates an example of a doping concentration distribution of a semiconductor device of a comparative example. The present drawing illustrates a distribution of a doping concentration of a lifetime control region 550 too.

A buffer region 520 has peaks with a plurality of doping concentrations. The buffer region 520 in the present example has four peaks including the first peak 61, the second peak 62, the third peak 63, and the fourth peak 64.

The lifetime control region 550 is provided in the front surface 21 side relative to the second peak 62 in the depth direction of the semiconductor substrate 10. That is, the lifetime control region 550 may be connected to the depletion layer extending from the lower surface side of the base region 14. In addition, the doping concentration at the peak of the lifetime control region 550 is smaller than the doping concentration at the first peak 61. With regard to the lifetime control region 550, the energy loss can be further reduced by increasing a light ion irradiation dose, but the leakage current starting from the generated lattice defect may increase.

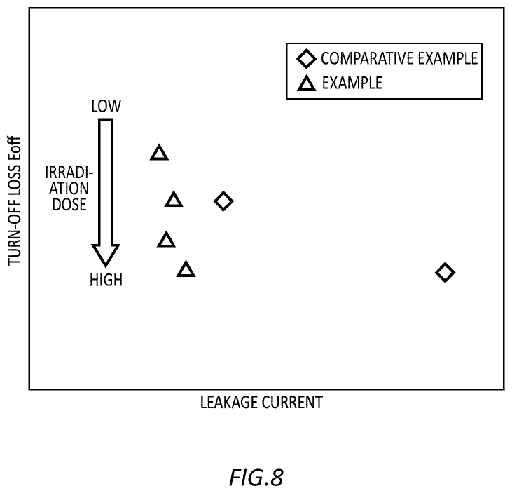

FIG. 8 is a graph representing a relationship between the leakage current and the turn-off loss Eoff. A vertical axis represents the turn-off loss Eoff, and a horizontal axis represents the leakage current. The present example illustrates results of both the example and the comparative example.

In the semiconductor device 100 of the example, even when the light ion irradiation dose for forming the first lifetime control region 151 is increased, the turn-off loss Eoff can be reduced while the increase in the leakage current is suppressed. On the other hand, in the semiconductor device of the comparative example, when the light ion irradiation dose for forming the lifetime control region 550 is increased, the leakage current starting from the generate lattice defect increases.

In this manner, in the semiconductor device 100 of the present example, by providing the peak of the lifetime killer concentration of the first lifetime control region 151 between the first peak 61 and the second peak 62, even when the doping concentration is increased, the leakage current can be suppressed.

While the present invention has been described with the embodiments, the technical scope of the present invention is not limited to the scope of the above described embodiments. It is apparent to persons skilled in the art that varied alteration or improvement can be added to the above embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending segment; 32: dummy dielectric film; 33: connecting segment; 34: dummy conductive portion; 38: interlayer dielectric film; 40: gate trench portion; 41: extending segment; 42: gate dielectric film; 43: connecting segment; 44: gate conductive portion; 50: gate metal layer; 52: emitter electrode; 54: contact hole; 55: contact hole; 56: contact hole; 61: first peak; 62: second peak; 63: third peak; 64: fourth peak; 70: transistor portion; 71: mesa portion; 80: diode portion; 81: mesa portion; 82: cathode region; 90: boundary portion; 91: mesa portion; 100: semiconductor device; 151: first lifetime control region; 152: second lifetime control region; 520: buffer region; 550: lifetime control region; 600: auxiliary peak group.

What is claimed is:

1. A semiconductor device comprising:
a drift region of a first conductivity type which is provided in a semiconductor substrate;
a buffer region of the first conductivity type which is provided in a back surface side of the semiconductor substrate relative to the drift region and which includes a first peak of a doping concentration and a second peak of the doping concentration which is provided in a front surface side of the semiconductor substrate relative to the first peak; and
a first lifetime control region provided between the first peak and the second peak in a depth direction of the semiconductor substrate.

2. The semiconductor device according to claim 1, wherein
an integrated concentration obtained by integrating a doping concentration in a direction from an upper end of the drift region to the second peak is a critical integrated concentration or more in the depth direction of the semiconductor substrate.

3. The semiconductor device according to claim 1, wherein
the buffer region includes a third peak of the doping concentration which is provided in the front surface side of the semiconductor substrate relative to the second peak, and
an integrated concentration from an upper end of the drift region to the third peak is less than a critical integrated concentration in the depth direction of the semiconductor substrate.

4. The semiconductor device according to claim 1, wherein
the first peak is a peak closest to a back surface of the semiconductor substrate among a plurality of peaks included in the buffer region.

5. The semiconductor device according to claim 1, wherein
the first lifetime control region is away from the second peak towards the back surface side by 0.5 μm or more in the depth direction of the semiconductor substrate.

6. The semiconductor device according to claim 1, wherein
the first lifetime control region is away from the first peak towards the front surface side by 1.0 μm or more in the depth direction of the semiconductor substrate.

7. The semiconductor device according to claim 1, wherein
the first peak is provided at a depth of 0.5 μm or more and 2.0 μm or less from a back surface of the semiconductor substrate.

8. The semiconductor device according to claim 1, wherein
the second peak is provided at a depth of 2.0 μm or more and 7.0 μm or less from a back surface of the semiconductor substrate.

9. The semiconductor device according to claim 1, wherein
a distance between the second peak and a peak of a lifetime killer concentration of the first lifetime control region is 0.2 μm or more in the depth direction of the semiconductor substrate.

10. The semiconductor device according to claim 1, comprising:
a collector region of a second conductivity type which is provided at a back surface of the semiconductor substrate, wherein
a distance between the second peak and a peak of a doping concentration of the first lifetime control region is smaller than a distance between an upper end of the collector region and the peak of the first lifetime control region in the depth direction of the semiconductor substrate.

11. The semiconductor device according to claim 1, comprising:
a collector region of a second conductivity type which is provided at a back surface of the semiconductor substrate, wherein
a distance between the second peak and a peak of a doping concentration of the first lifetime control region is larger than a distance between an upper end of the collector region and the peak of the first lifetime control region in the depth direction of the semiconductor substrate.

12. The semiconductor device according to claim 10, wherein
the distance between the upper end of the collector region and the peak of the first lifetime control region is 0.1 μm or more in the depth direction of the semiconductor substrate.

13. The semiconductor device according to claim 10, wherein
a doping concentration at a peak of the first lifetime control region is larger than a doping concentration at the first peak and smaller than a doping concentration at a peak of the collector region.

14. The semiconductor device according to claim 10, wherein
a doping concentration at a peak of the collector region is 1.0 E17 cm⁻³ or more and 1.0 E19 cm⁻³ or less.

15. The semiconductor device according to claim 1, wherein
a doping concentration at a peak of the first lifetime control region is 1.0 E15 cm⁻³ or more and 1.0 E17 cm⁻³ or less.

16. The semiconductor device according to claim 1, wherein
a full width at half maximum of a peak of a doping concentration of the first lifetime control region is 0.5 μm or less.

17. The semiconductor device according to claim 1, comprising:
a transistor portion and a diode portion which are provided in the semiconductor substrate.

18. The semiconductor device according to claim 1, wherein
the drift region includes a second lifetime control region in the front surface side of the semiconductor substrate relative to the first lifetime control region.

19. The semiconductor device according to claim 18, wherein
a doping concentration at a peak of the second lifetime control region is smaller than a doping concentration at a peak of the first lifetime control region.

20. A semiconductor device comprising:
a drift region of a first conductivity type which is provided in a semiconductor substrate; and
a buffer region of the first conductivity type which is provided in a back surface side of the semiconductor substrate relative to the drift region and which includes a plurality of peaks of a doping concentration, wherein
the buffer region includes:
a first peak provided to be closest to the back surface side of the semiconductor substrate among the plurality of peaks included in the buffer region;
an auxiliary peak group which is provided in a front surface side of the semiconductor substrate relative to the first peak and which includes one or more peaks of a doping concentration; and
a first lifetime control region provided in the auxiliary peak group.

21. The semiconductor device according to claim 20, wherein
a position at which an integrated concentration obtained by integrating a doping concentration in a direction from an upper end of the drift region towards the back surface side becomes a critical integrated concentration is at the auxiliary peak group in a depth direction of the semiconductor substrate.

22. The semiconductor device according to claim 21, wherein
a peak position of a lifetime killer concentration of the first lifetime control region is away towards the back surface side by 0.1 μm or more from the position at which the integrated concentration becomes the critical integrated concentration.

23. The semiconductor device according to claim 21, wherein
one peak in the auxiliary peak group includes, in a range of a full width at half maximum of the one peak, the position at which the integrated concentration becomes the critical integrated concentration.

24. The semiconductor device according to claim 23, wherein
the peak position of the lifetime killer concentration of the first lifetime control region is away towards the back surface side by 0.1 μm or more from a position of the one peak in the auxiliary peak group which includes the position at which the integrated concentration becomes the critical integrated concentration.

25. The semiconductor device according to claim 23, wherein
a doping concentration at the one peak in the auxiliary peak group is 3.0 E15 cm⁻³ or more.

26. The semiconductor device according to claim 23, wherein
the one peak in the auxiliary peak group is a second peak adjacent to the front surface side of the first peak.

27. The semiconductor device according to claim 20, wherein
a doping concentration at each peak in the auxiliary peak group is smaller than a doping concentration at the first peak.

28. The semiconductor device according to claim 27, wherein
the auxiliary peak group includes a plurality of peaks, and
doping concentrations of the plurality of peaks in the auxiliary peak group decrease towards the front surface side.

29. A manufacturing method of a semiconductor device, comprising:
providing a drift region of a first conductivity type in a semiconductor substrate;
providing a buffer region of the first conductivity type in a back surface side of the semiconductor substrate relative to the drift region; and
providing a first lifetime control region in the buffer region, wherein
the buffer region includes a first peak of a doping concentration and a second peak of the doping concentration which is provided in a front surface side of the semiconductor substrate relative to the first peak, and
the first lifetime control region is provided between the first peak and the second peak in a depth direction of the semiconductor substrate.

30. The manufacturing method of a semiconductor device according to claim 29, wherein
an ion dose amount for forming the first lifetime control region is 0.1 times or more and 10 times or less an ion dose amount for forming the first peak.

31. The manufacturing method of a semiconductor device according to claim 29, wherein
acceleration energy for forming the first lifetime control region is 50 keV or more and 2000 keV or less.

32. The manufacturing method of a semiconductor device according to claim 29, comprising:
forming a collector region of a second conductivity type at a back surface of the semiconductor substrate, wherein
an ion dose amount for forming the collector region is 2.0 E13/cm² or more and 5.0 E13/cm² or less.

33. The manufacturing method of a semiconductor device according to claim 32, wherein
the ion dose amount for forming the collector region is ten times or more and 50 times or less an ion dose amount for forming the first peak.

34. The manufacturing method of a semiconductor device according to claim 32, wherein
the ion dose amount for forming the collector region is 300 times or more and 500 times or less an ion dose amount for forming the first lifetime control region.
